(19) United States
(12) Patent Application Publication
(10) Pub. No.: US 2025/0248197 A1
(43) Pub. Date: Jul. 31, 2025

(54) LIGHT-EMITTING DEVICE

(71) Applicant: NICHIA CORPORATION, Tokushima (JP)

(72) Inventor: Hiroki YUU, Anan-shi (JP)

(21) Appl. No.: 19/036,661

(22) Filed: Jan. 24, 2025

(30) Foreign Application Priority Data
Jan. 29, 2024 (JP) 2024-010818

(51) Int. Cl. H10H 29/851

(52) U.S. Cl. CPC H10H 29/8514

(57) ABSTRACT

A light-emitting device includes a substrate; light-emitting elements on an upper surface of the substrate, the light-emitting elements configured to be individually driven; a first wavelength conversion portion covering at least a portion of at least one of the light-emitting elements; a second wavelength conversion portion covering a part of the first wavelength conversion portion; and a diffusion portion covering the first and second wavelength conversion portions. In a cross-sectional view, the light-emitting device includes a first region in which the diffusion portion is arranged above the first wavelength conversion portion without the second wavelength conversion portion between them, and a second region in which the second wavelength conversion portion and the diffusion portion are sequentially arranged on the first wavelength conversion portion. A color temperature of light extracted from the second region is lower than a color temperature of light extracted from the first region.

### CROSS-REFERENCE TO RELATED APPLICATION

This application claims priority to Japanese Patent Application No. 2024-010818 filed on Jan. 29, 2024, the disclosure of which is hereby incorporated by reference in its entirety.

### BACKGROUND

### Technical Field

The present disclosure relates to a light-emitting device.

### Background Art

A known light-emitting device includes a substrate, a plurality of light-emitting elements mounted on the substrate, a first wavelength conversion member covering at least parts of upper surfaces and at least parts of lateral surfaces, that face each other, of at least two light-emitting elements of the plurality of light-emitting elements and not covering at least parts of lateral surfaces, that do not face each other, of the at least two light-emitting elements, and a sealing material sealing the plurality of light-emitting elements and the first wavelength conversion member. For example, see WO 2021/182413.

### SUMMARY

One object of the present disclosure is to provide a light-emitting device in which illumination and emission color can be adjusted.

A light-emitting device according to an embodiment of the present disclosure includes: a substrate; a plurality of light-emitting elements arranged on an upper surface of the substrate, the plurality of light-emitting elements configured to be individually driven; a first wavelength conversion portion covering at least a portion of at least one of the plurality of light-emitting elements; a second wavelength conversion portion covering a part of the first wavelength conversion portion; and a diffusion portion covering the first wavelength conversion portion and the second wavelength conversion portion. In a cross-sectional view, the light-emitting device comprises a first region in which the diffusion portion is arranged above the first wavelength conversion portion without the second wavelength conversion portion between the diffusion portion and the first wavelength conversion portion, and a second region in which the second wavelength conversion portion and the diffusion portion are sequentially arranged on the first wavelength conversion portion. A color temperature of light extracted from the second region is lower than a color temperature of light extracted from the first region.

According to certain embodiments of the present disclosure, a light-emitting device that can perform illumination adjustment and color adjustment can be provided.

### BRIEF DESCRIPTION OF DRAWINGS

FIG. 1 is a perspective view schematically illustrating a light-emitting device according to a first embodiment;

FIG. 2 is a perspective view schematically illustrating a configuration of the light-emitting device according to the first embodiment, from which illustration of a part of the configuration is omitted;

FIG. 3 is a top view schematically illustrating the light-emitting device according to the first embodiment;

FIG. 4 is a schematic cross-sectional view taken along line IV-IV in FIG. 3;

FIG. 5 is a top view schematically illustrating a light-emitting device according to a second embodiment;

FIG. 6 is a schematic cross-sectional view taken along line VI-VI in FIG. 5;

FIG. 7 is a cross-sectional view schematically illustrating a light-emitting device according to a third embodiment;

FIG. 8 is a cross-sectional view schematically illustrating a light-emitting device according to a fourth embodiment;

FIG. 9 is a cross-sectional view schematically illustrating a light-emitting device according to a fifth embodiment;

FIG. 10 is a top view schematically illustrating a light-emitting device according to a sixth embodiment.

### DETAILED DESCRIPTION

A light-emitting device according to the present disclosure (may be referred to as a “light-emitting device according to an embodiment” hereinafter) will be described below with reference to the drawings. In the following description, terms indicating a specific direction or position (for example, “upper”, “lower”, and other terms including those terms) are used as necessary. However, the use of those terms is to facilitate understanding of the invention with reference to the drawings, and the technical scope of the present disclosure is not limited by the meanings of those terms. Parts having the same reference signs appearing in a plurality of drawings indicate identical or equivalent parts or members.

Further, the following embodiments exemplify a light-emitting device and the like for embodying a technical concept of the present invention, but the present invention is not limited to the description below. The dimensions, materials, shapes, relative arrangements, and the like of constituent components described below are not intended to limit the scope of the present invention to those alone, but are intended to provide an example, unless otherwise specified. The contents described in one embodiment can be applied to any of the other embodiments and modified examples. The sizes, the positional relationship, and the like of the members illustrated in the drawings may be exaggerated in order to clarify the explanation. Furthermore, in order to avoid excessive complication of the drawings, a schematic view in which some elements are not illustrated may be used, or an end view illustrating only a cutting surface may be used as a cross-sectional view.

### First Embodiment

A light-emitting device according to the present disclosure includes a substrate, a plurality of light-emitting elements arranged on an upper surface of the substrate, the plurality of light-emitting elements configured to be driven individually, a first wavelength conversion portion covering at least a portion of at least one of the plurality of light-emitting elements, a second wavelength conversion portion covering a part of the first wavelength conversion portion, a diffusion portion covering the first wavelength conversion portion and the second wavelength conversion portion. In a cross-sectional view, the light emitting device includes a first region in which the diffusion portion is arranged above the first wavelength conversion portion without the second wavelength conversion portion therebetween, and a second region in which the second wavelength conversion portion and the diffusion portion are sequentially arranged above the first wavelength conversion portion. A color temperature of light extracted from the second region is lower than a color temperature of light extracted from the first region.

### Light-Emitting Device 1

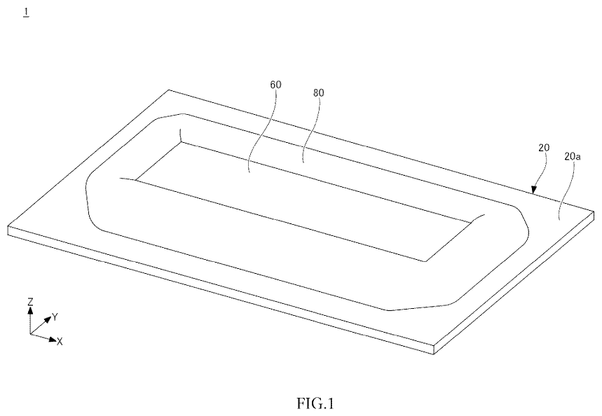

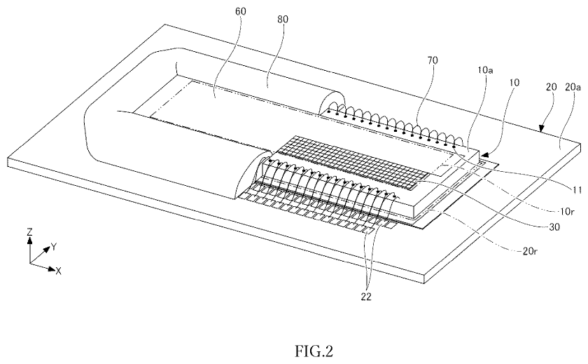

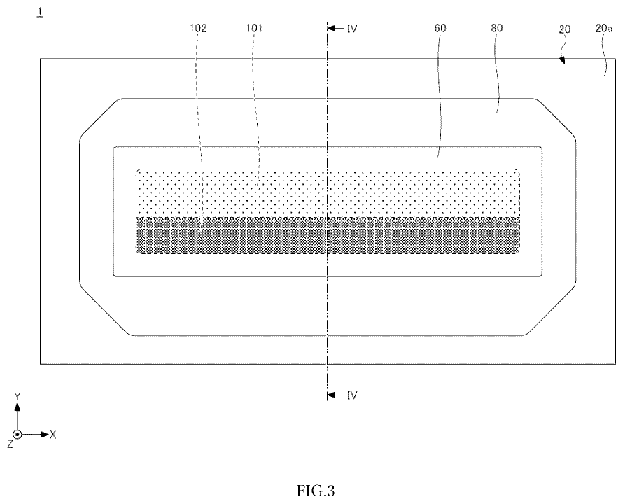

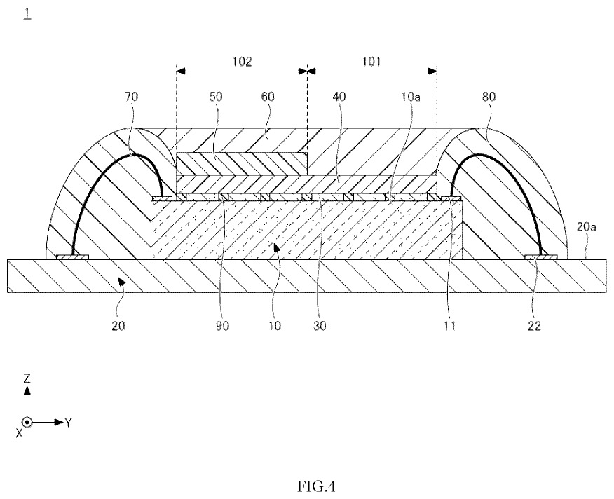

A light-emitting device 1 will be described as an example of the light-emitting device according to the present disclosure. FIG. 1 is a perspective view schematically illustrating a light-emitting device according to a first embodiment. FIG. 2 is a perspective view schematically illustrating a configuration of the light-emitting device according to the first embodiment, from which illustration of a part of the configuration is omitted. FIG. 3 is atop view schematically illustrating the light-emitting device according to the first embodiment. FIG. 4 is a schematic cross-sectional view taken along line IV-IV in FIG. 3.

Note that, in each of the drawings, an X-axis, a Y-axis, and a Z-axis, which are orthogonal to each other, are illustrated for reference as necessary. A direction parallel to the X-axis is referred to as an X direction, a direction parallel to the Y-axis is referred to as a Y direction, and a direction parallel to the Z-axis is referred to as a Z direction. In addition, in the X direction, a direction in which an arrow is directed is referred to as a +X direction, and a direction opposite to the +X direction is referred to as a −X direction. In the Y direction, a direction in which an arrow is directed is referred to as a +Y direction, and a direction opposite to the +Y direction is referred to as a −Y direction. In the Z direction, a direction in which an arrow is directed is referred to as a +Z direction, and a direction opposite to the +Z direction is referred to as a −Z direction. However, these description of directions do not limit the orientation of the light-emitting device during use, and the light-emitting device may be oriented in any direction during use. Furthermore, a view in which a target object is viewed from a the +Z direction side toward the −Z direction side is referred to as a top view.

As illustrated in FIGS. 1 to 4, the light-emitting device 1 includes a substrate 10 and a plurality of light-emitting elements 30 disposed on an upper surface 10a of the substrate 10. The plurality of light-emitting elements 30 can be individually driven. The light-emitting device 1 also includes a first wavelength conversion portion 40 covering at least a portion of at least one of the plurality of light-emitting elements 30, a second wavelength conversion portion 50 covering a part of the first wavelength conversion portion 40, and a diffusion portion 60 covering the first wavelength conversion portion 40 and the second wavelength conversion portion 50. In the first embodiment, the first wavelength conversion portion 40 covers all of the plurality of light-emitting elements 30.

The light-emitting device 1 may further include a package substrate 20, wires 70, a covering member 80, and a reflective member 90. In the examples of FIGS. 1 to 4, the substrate 10 is mounted on an upper surface 20a of the package substrate 20. First terminals 11 are arranged on the upper surface 10a of the substrate 10, at locations outside a region where the plurality of light-emitting elements 30 are disposed. The package substrate 20 is larger than the substrate 10 in a top view. Second terminals 22 are arranged on the upper surface 20a of the package substrate 20, at locations outside a region where the substrate 10 is mounted. Each of the first terminals 11 of the substrate 10 is electrically connected by a corresponding one of the wires 70 to a corresponding one of the second terminals 22 of the package substrate 20. The first terminals 11, the second terminals 22, and the wires 70 are covered by the covering member 80 arranged on an outer peripheral portion of the upper surface 10a of the substrate 10 and an outer peripheral portion of the upper surface 20a of the package substrate 20. Upper surfaces of the plurality of light-emitting elements 30 are exposed from the reflective member 90, and the reflective member 90 covers lateral surfaces thereof.

In FIG. 2, for convenience of illustration, illustrations of a part of each of the first wavelength conversion portion 40, the second wavelength conversion portion 50, the diffusion portion 60, and the covering member 80 is omitted, and a part of each of the light-emitting elements 30, the wires 70, and the like is shown. In FIG. 3, a first region 101 is indicated by a low-density dot pattern and a second region 102 is indicated by a high-density dot pattern, for convenience.

The light-emitting device 1 includes, in a cross-sectional view, the first region 101, in which the diffusion portion 60 is arranged on the first wavelength conversion portion 40 without the second wavelength conversion portion 50 therebetween, and the second region 102, in which the second wavelength conversion portion 50 and the diffusion portion 60 are sequentially arranged on the first wavelength conversion portion 40. The second wavelength conversion portion 50 may be arranged at any position on a part of the upper surface of the first wavelength conversion portion 40. The first region 101 and the second region 102 may be positioned inward of the covering member 80, in a top view.

The first wavelength conversion portion 40 converts incident light into light having a different wavelength, and emits the converted light. A part of the incident light may exit the first wavelength conversion portion 40 without being converted into light having a different wavelength, or the first wavelength conversion portion 40 may convert an entirety of the incident light into light having a different wavelength and emit the converted light. For example, the thickness of the first wavelength conversion portion 40 can be substantially uniform. The second wavelength conversion portion 50 converts incident light into light having a different wavelength, and emits the converted light. Apart of the incident light may exit the second wavelength conversion portion 50 without being converted into light having a different wavelength, or the second wavelength conversion portion 50 may convert all of the incident light into light having a different wavelength and emit the converted light. For example, the thickness of the second wavelength conversion portion 50 can be substantially uniform. The diffusion portion 60 diffuses and emits incident light. The diffusion portion 60 does not perform wavelength conversion.

Light emitted from the light-emitting elements 30 and light emitted from the light-emitting elements 30 and wavelength-converted by the first wavelength conversion portion can be extracted from the first region 101 via the diffusion portion 60. The light emitted from the light-emitting elements 30, the light emitted from the light-emitting elements 30 and wavelength-converted by the first wavelength conversion portion 40, the light emitted from the light-emitting elements 30 and wavelength-converted by the second wavelength conversion portion 50, and the light emitted from the light-emitting elements 30 and wavelength-converted by the first wavelength conversion portion 40 and the second wavelength conversion portion 50 can be extracted from the second region 102 via the diffusion portion 60.

The light emission peak wavelength of light wavelength-converted by the first wavelength conversion portion 40 is shorter than the light emission peak wavelength of light wavelength-converted by the second wavelength conversion portion 50. Thus, the color temperature of the light extracted from the second region 102 is lower than the color temperature of the light extracted from the first region 101.

In the light-emitting device 1, the plurality of light-emitting elements 30 are configured to be individually driven. Therefore, for example, when some or all of the plurality of light-emitting elements 30 located in the first region 101 is turned on and all of the plurality of light-emitting elements 30 located in the second region 102 is turned off, it is possible to extract light only from the first region 101. Furthermore, it is possible to adjust illumination by controlling the number of light-emitting elements 30 caused to emit light, among the plurality of light-emitting elements 30 located in the first region 101. Alternatively, it is possible to adjust illumination by controlling the value of a current flowing in each of the plurality of light-emitting elements 30 located in the first region 101.

Furthermore, by causing some or all of the plurality of light-emitting elements 30 located in the second region 102 to be turned on and causing all of the plurality of light-emitting elements 30 located in the first region 101 to be turned off, it is possible to extract light only from the second region 102. Moreover, it is possible to adjust illumination by controlling the number of light-emitting elements 30 caused to emit light, among the plurality of light-emitting elements 30 located in the second region 102. Alternatively, it is possible to adjust illumination by controlling the value of a current flowing in each of the plurality of light-emitting elements 30 located in the second region 102.

Light can be extracted from both the first region 101 and the second region 102 by causing some or all of the plurality of light-emitting elements 30 located in the first region 101 and the second region 102 to emit light. In this case, the light from the first region 101 and the light from the second region 102 are mixed, so that mixed-color light is emitted from the light-emitting device 1. In this case, illumination can also be controlled by controlling the number of light-emitting elements 30 caused to emit light and the value of the current.

As described above, in the light-emitting device 1, by selecting the light-emitting elements 30 to be turned on among the plurality of light-emitting elements 30, it is possible to perform illumination adjustment and color adjustment using a single light source. Furthermore, the light-emitting device 1 includes the diffusion portion 60, and light is emitted from the diffusion portion 60 in various directions. Therefore, when light is extracted from both the first region 101 and the second region 102, the light from each region is easily mixed, and the color mixing performance can be improved.

The constituent components of the light-emitting device 1 are described below.

### Substrate 10

The substrate 10 includes a support member having a flat plate shape and a conductive member arranged on an upper surface side of the support member. The upper surface 10a of the substrate 10 has an element placement region 10r in which the plurality of light-emitting elements 30 are placed, and a conductive member is arranged in the element placement region 10r. The substrate 10 includes a plurality of first terminals 11 arranged on the upper surface 10a outward from the element placement region 10r, and the first terminals 11 are electrically connected to the conductive member arranged in the element placement region 10r.

For example, in atop view, the substrate 10 and the element placement region 10r may each have a rectangular shape having long sides and short sides. The plurality of light-emitting elements 30 are arranged in a matrix shape in the element placement region 10r, for example. Each of the plurality of light-emitting elements 30 is electrically connected to a corresponding one of the first terminals 11. For example, the plurality of light-emitting elements 30 can be connected in series or in parallel with the first terminals 11, as a group including a predetermined number of components. The length of the long sides of the element placement region 10r can be in a range from 8 mm to 18 mm and the length of the short sides can be in a range from 2 mm to 6 mm, for example.

Each of the first terminals 11 has a substantially circular shape, a substantially elliptical shape, or a substantially rectangular shape, for example. The first terminals 11 are arranged on the upper surface 10a of the substrate 10 in rows along long sides, opposite to each other, of the element placement region 10r having a rectangular shape such that the first terminals 11 in each row are spaced apart from one another and the element placement region 10r are located between the rows of the first terminals 11 along the opposite long sides. An interval between adjacent ones of the first terminals 11 may or may not be constant. The interval between adjacent ones of the first terminals 11 can be in a range from 20 μm to 100 μm, for example. One end of each of the wires 70 is connected to a corresponding one of the first terminals 11.

The substrate 10 is, for example, a semiconductor substrate such as a silicon substrate. A region of the upper surface 10a of the substrate 10 where no conductive member is arranged is covered with an insulating film, for example. The conductive member may also be arranged inside the support member or on a lower surface of the support member. For example, an integrated circuit board with an integrated circuit for individually driving and controlling the plurality of light-emitting elements 30 may be used as the substrate 10.

Examples of the material of the first terminals 11 and the conductive member include metals such as Cu, Ag, Au, Al, Pt, Ti, W, Pd, Fe, and Ni, and/or alloys containing at least any of these metals.

### Package Substrate 20

The package substrate 20 includes a base material having a flat plate shape and a conductive member arranged at least on an upper surface side of the base material. The package substrate 20 includes, on the upper surface 20a, a substrate placement region 20r where the substrate 10 is disposed, and further includes the second terminals 22 on the upper surface 20a outward of the substrate placement region 20r. The substrate placement region 20r is a region where the substrate 10 is placed. The substrate placement region 20r is set as a region having an area size substantially equal to the shape of the substrate 10 in a top view. When the substrate 10 is rectangular in a top view, the substrate placement region 20r may also be rectangular. Here, the meaning of “substantially equal” includes, as a tolerance range, variation in size attributed to component tolerance or mounting tolerance.

Each of the second terminals 22 has a substantially circular shape, a substantially elliptical shape, or a substantially rectangular shape, for example. The second terminals 22 are arranged on the upper surface 20a of the package substrate 20 in rows along long sides, opposite to each other, of the rectangular shape such that the second terminals 22 in each row are spaced apart from one another and the substrate placement region 20r is located between rows of the second terminals 22 along the opposite long sides. An interval between adjacent ones of the second terminals 22 may be constant or may not be constant. The interval between adjacent ones of the second terminals 22 can be in a range from 20 μm to 100 μm, for example. The other end of each of the wires 70 is connected to a corresponding one of the second terminals 22.

A material having strong heat dissipation is preferably used as the base material constituting the package substrate 20, and a material having a strong light-shielding property and base material strength is more preferably used. Specific examples of the base material include metals such as Al and Cu; ceramics such as aluminum oxide, aluminum nitride, silicon nitride, and mullite; resins such as phenol resin, epoxy resin, polyimide resin, bismaleimide triazine resin (BT resin), and polyphthalamide (PPA), and further, graphite, and composite materials formed from a resin and a metal or a ceramic (for example, an inlay substrate obtained by fitting metal members into a resin). A base material having a flat plate shape or having a recess on an upper surface may be used as the base material. In this case, the bottom of the recess can serve as the substrate placement region 20r of the package substrate 20, and the substrate 10 can be disposed inside the recess.

The package substrate 20 may include a conductive member for placing the substrate 10 on the surface of the substrate placement region 20r.

### Light-Emitting Element

For example, in a top view, each of the light-emitting elements 30 has a substantially rectangular shape. In a top view, the shape of the light-emitting element 30 can be a square of which each side is in a range from 40 μm to 100 μm, for example. The light-emitting element 30 includes a positive electrode and a negative electrode on the same surface side and is flip chip-mounted on the substrate 10 with the surface of the light-emitting element 30 provided with the electrodes being a lower surface thereof. In this case, the upper surface positioned opposite to the surface where the electrodes are disposed serves as a main light-extracting surface of the light-emitting element 30.

In the light-emitting device 1, the light-emitting elements 30 are arranged on the substrate 10 and aligned in rows at predetermined intervals in directions of a matrix. The size and the number of the light-emitting elements 30 being used can be selected as appropriate, depending on the form of the desired light-emitting device. Regarding the size and the number of the light-emitting elements 30, it is preferable to arrange small light-emitting elements 30 at a high density. This allows for controlling the irradiation area of light emitted from the light-emitting device 1 with a larger number of divisions. Such a light-emitting device 1 can be used as a light source of a high-resolution illumination system. For example, the number of the light-emitting elements 30 included in the light-emitting device 1 can be in a range from 1000 to 100000.

For example, the light-emitting elements 30 are light-emitting diodes. Each of the light-emitting elements 30 has a semiconductor structure. The semiconductor structure includes an n-side semiconductor layer, a p-side semiconductor layer, and an active layer located between the n-side semiconductor layer and the p-side semiconductor layer. The active layer may have a single quantum well (SQW) structure, or may have a multi quantum well (MQW) structure including a plurality of well layers. The active layer is configured to emit visible light or ultraviolet light, for example.

The semiconductor structure may include a plurality of light-emitting portions each including the n-side semiconductor layer, the active layer, and the p-side semiconductor layer. When the semiconductor structure includes the plurality of light-emitting portions, the plurality of light-emitting portions may each include well layers having different light emission peak wavelengths or well layers having the same light emission peak wavelength. The phrase having the same light emission peak wavelength includes a case in which there is a variation of about a few nanometers. The combination of the light emission peak wavelengths of the plurality of light-emitting portions can be selected as appropriate. When the semiconductor structure includes two light-emitting portions, examples of combinations of light emitted from the light-emitting portions include a combination of blue light and blue light, a combination of green light and green light, a combination of ultraviolet light and ultraviolet light, a combination of blue light and green light, a combination of blue light and ultraviolet light, and a combination of green light and ultraviolet light. When the semiconductor structure includes three light-emitting portions, examples of the combinations of light emitted from the light-emitting portions include a combination of blue light, green light, and red light. Each of the light-emitting portions may include one or more well layers having light emission peak wavelengths different from the light emission peak wavelengths of other well layers.

As the light-emitting element 30, for example, a light-emitting element configured to emit blue light (light having a wavelength in a range from 430 nm to 490 nm) can be employed. For the color of the light emitted from the light-emitting element 30, any wavelength can be selected in accordance with the application. For example, for light-emitting elements that emit blue light (light having a wavelength in a range from 430 nm to 490 nm) and light-emitting elements that emit green light (light having a wavelength in a range from 495 nm to 565 nm), light-emitting elements using a nitride-based semiconductor (InₓAl_{y}Ga_{1-x-y}N (0≤x, 0≤y, x+y≤1)), GaP, or the like can be used. For light-emitting elements that emit red light (light having a wavelength in a range from 610 nm to 700 nm), a nitride-based semiconductor element, GaAlAs, AlInGaP, or the like can be used.

The light-emitting elements 30 are joined by an electrically conductive bonding member on a conductive member arranged in the element placement region 10r of the substrate 10. In a case in which the light-emitting elements 30 are flip-chip mounted on the substrate 10, a bump formed of a metal material such as Au, Ag, Cu, or Al can be used as the bonding member. Furthermore, a solder such as an AuSn-based alloy and an Sn-based lead-free solder may be used as the bonding member. Alternatively, an electrically conductive adhesive material including electrically conductive particles such as metal particles in a resin can be used as the bonding member. The bond between the light-emitting elements 30 and the substrate 10 may be formed using a plating method. Examples of the plating material include Cu and Au. Regarding the electrodes of the light-emitting elements 30 and the conductive member of the substrate 10, the electrodes of the light-emitting elements 30 and the conductive member of the substrate 10 may also be in direct contact with each other, without interposing a bonding member.

### First Wavelength Conversion Portion

The first wavelength conversion portion 40 includes, for example, a resin and a phosphor. Examples of the resin include known light-transmissive resins such as a silicone resin and an epoxy resin. Among these resins, a silicone resin having good reliability (specifically, a resin having transmissivity such as a phenyl silicone resin and a dimethyl silicone resin) can be suitably used.

Examples of the phosphor include an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), oxynitride-based phosphors such as a β-SiAlON-based phosphor (for example, (Si,Al)₃(O,N)₄:Eu) and an α-SiAlON-based phosphor (for example, Ca(Si,Al)₁₂(O,N)₁₆:Eu), nitride phosphors such as an LSN-based phosphor (for example, (La,Y)₃Si₆Ni₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr,Ca)AlSiN₃:Eu), fluoride phosphors such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a II-VI group quantum dot (for example, CdSe), a III-V group quantum dot (for example, InP), and a quantum dot having a chalcopyrite structure (for example, (Ag,Cu)(In,Ga)(S,Se)₂).

When the light-emitting elements 30 is configured to emit blue light, the first wavelength conversion portion 40 can be configured to be excited by the blue light and to emit yellow light, for example. In this case, examples of the phosphor contained in the first wavelength conversion portion 40 include an yttrium aluminum garnet-based phosphor (for example, (Y,Gd)₃(Al,Ga)₅O₁₂:Ce). According to such a configuration, blue light that is transmitted through the first wavelength conversion portion 40 and yellow light emitted from the first wavelength conversion portion 40 are mixed, so that white light is emitted from the first region 101 as a result of the color-mixing.

### Second Wavelength Conversion Portion

The second wavelength conversion portion 50 includes, for example, a resin and a phosphor. As the resin and the phosphor, the resins and the phosphors exemplified above as a material of the first wavelength conversion portion 40 can be used.

When each of the light-emitting elements 30 is configured to emit blue light, the second wavelength conversion portion 50 can be configured to be excited by the blue light and to emit amber light, for example. In this case, examples of the phosphor contained in the second wavelength conversion portion 50 include a nitride phosphor such as a CASN-based phosphor (for example, CaAlSiN₃:Eu) and an SCASN-based phosphor (for example, (Sr,Ca)AlSiN₃:Eu), and a KSF-based phosphor (for example, K₂SiF₆:Mn).

When the light-emitting element 30 is configured to emit blue light, the first wavelength conversion portion 40 is configured to emit yellow light, and the second wavelength conversion portion 50 is configured to emit amber light, white light having a lower color temperature than white light emitted from the first region 101 is emitted from the second region 102 by color-mixing of blue light transmitted through the first wavelength conversion portion 40 and the second wavelength conversion portion 50, yellow light emitted from the first wavelength conversion portion 40 and transmitted through the second wavelength conversion portion 50, and amber light emitted from the second wavelength conversion portion 50.

### Diffusion Portion

The diffusion portion 60 includes a resin and a light diffusion material, for example. As the resin, the resins exemplified above as a material of the first wavelength conversion portion 40 can be used. Examples of the light diffusion material that can be used include titanium oxide, zinc oxide, silicon oxide, zirconium oxide, aluminum oxide, and aluminum nitride.

### Wire

For the wires 70, metals such as Au, Ag, Cu, Pt, and Al and/or an alloy containing at least any of these metals can be used. In particular, Au having good thermal resistance and the like is preferably used. For example, the diameter of the wires 70 may be in a range from 15 μm to 50 μm. Each wire 70 may extend across the long side of the substrate 10 having a substantially rectangular shape in a top view and, for example, and may extend substantially orthogonally to the long side. Furthermore, among a plurality of wires 70 arranged in rows along the long side of the substrate 10, the wire 70 positioned at the center of a row may be arranged to be substantially orthogonal to the long side of the substrate 10 in a top view, as described above, and the wire 70 positioned at an end side of a row may be arranged to be oblique with respect to the long side of the substrate 10 in a top view. The interval in which the rows of the wires 70 are arranged can be in a range from 20 μm to 100 μm.

### Covering Member

The covering member 80 is a light-shielding member covering the wires 70 located outward from the element placement region 10r. For example, the covering member 80 is arranged in a frame-like shape in a top view, so as to cover the wires 70 and surround the element placement region 10r.

The covering member 80 is separated from the light-emitting elements 30 in a top view. The covering member 80 is preferably disposed so that the height of the covering member 80 (that is, the distance from the upper surface 20a of the package substrate 20 to the upper surface of the covering member 80) is the highest at a position directly above a top portion of each of the wires 70. In other words, the covering member 80 is preferably disposed such that a top portion of the covering member 80 overlaps with the top portions of the wires 70.

Examples of the covering member 80 include a resin containing a filler having light-shielding properties. Examples of the resin serving as a base material that can be used include a silicone resin, a modified silicone resin, an epoxy resin, a modified epoxy resin, and an acrylic resin. For the filler having light-shielding properties, pigments, light-absorbing materials such as carbon black, titanium black, and graphite, and light reflective materials such as titanium oxide, aluminum oxide, zinc oxide, barium carbonate, barium sulfate, boron nitride, aluminum nitride, and a glass filler can be suitably used. Specific examples of the appearance color of the covering member 80 include white materials having excellent light reflectivity, black materials having excellent light absorption, and gray materials having light reflectivity and light absorption. Furthermore, the covering member 80 may include a plurality of resin layers. Among these, in consideration of the deterioration of the resin due to light absorption in the covering member 80, a light-reflective white resin is used at least at the outermost surface of the covering member 80.

### Reflective Member

The reflective member 90 is a member covering the upper surface 10a of the substrate 10 and the lateral surfaces of the light-emitting elements 30. The upper surfaces of the light-emitting elements 30 are exposed from the reflective member 90. The reflective member 90 may cover the space between the lower surfaces of the light-emitting elements 30 and the substrate 10. The reflective member 90 can reflect upwards light emitted from the lateral surfaces of the light-emitting elements 30. Thus, the light extraction efficiency of the light-emitting device 1 can be improved. Furthermore, when the light-emitting elements 30 are individually turned on, the boundary between a light-emitting area and a non-light-emitting area can be made clear. This improves the contrast ratio between the light-emitting area and the non-light-emitting area.

A soft resin having relatively low elasticity and good shape conformability is preferably used as the reflective member 90.

A resin material having high transmittance and insulation properties, for example, a thermosetting resin such as an epoxy resin or a silicone resin, can be suitably used as the material of the reflective member 90. Furthermore, a white resin in which a resin serving as a base body contains particles of a light reflective material is preferably used as the reflective member 90. Examples of the light reflective material include a light reflective material similar to the light reflective materials included in the covering member described above. The reflective member 90 may contain a light-absorbing material such as carbon black, titanium black, and graphite.

The light-emitting device 1 having the configuration described above can be used as a light source of a vehicular headlight, for example. In the configuration of this case, light is irradiated from the light source to the outside via a lens. In the light-emitting device 1, illumination adjustment and color adjustment can be performed by a single light source, and thus, a size of a vehicular headlight can be reduced.

The visibility of light emitted from a vehicular headlight varies depending on the weather and the like. In order to improve the visibility of the light emitted from a vehicular headlight, it is preferable to use light having a high color temperature on a sunny day and light having a low color temperature or both light having a high color temperature and light having a low color temperature on a rainy or foggy day. Such control can be performed by using the light-emitting device 1 as the light source of the vehicular headlight.

When the light-emitting device 1 is used as the light source of a vehicular headlight, the area size of the first region 101 is preferably larger than the area size of the second region 102 in a top view. The area of the first region 101 is more preferably in a range from 105% to 130% of the area size of the second region 102 in a top view. In rain or fog, light having a higher color temperature scatters more and thus has a lower transmittance. By setting the relationship between the area sizes of the first region 101 and the second region 102 as described above, light having a high color temperature can reach farther, even in rain or fog. As a result, when light is extracted from the first region 101 and the second region 102 in rainy or foggy weather, the brightness of the regions can be made uniform.

### Method of Manufacturing Light-Emitting Device 1

### Step of Mounting Light-Emitting Elements 30 on Substrate 10

First, the substrate 10 is provided that includes, on the upper surface 10a, the element placement region 10r and the first terminals 11 arranged outside the element placement region 10r. For example, the substrate 10 can be provided as follows. A support member having a flat plate shape such as a silicon member is provided, and a conductive member and the first terminals 11 are formed by a plating method, a sputtering method, a vapor deposition method, or the like. In the description of the manufacturing method, “providing” a member is not limited to manufacturing the member and includes obtaining the member such as purchasing the member or receiving the member.

Subsequently, the light-emitting elements 30 are mounted on the element placement region 10r of the substrate 10. The light-emitting elements 30 can be mounted by flip-chip mounting on the element placement region 10r of the upper surface 10a of the substrate 10. The light-emitting elements 30 can be provided by performing some or all of a plurality of steps such as a step of forming a semiconductor layered body and a step of forming an element electrode.

If necessary, after the light-emitting elements 30 are placed on the element placement region 10r of the substrate 10, a step of covering the lateral surfaces of the light-emitting elements 30 by the reflective member 90 may be included. For example, after the light-emitting elements 30 are placed on the substrate 10, a mask that covers the first terminals 11 and exposes the element placement region 10r is arranged. Subsequently, the reflective member 90 such as an uncured white resin is arranged in a region separated from the light-emitting elements 30, and the white resin is caused to flow to a position between lateral surfaces, that face each other, of adjacent ones of the light-emitting elements 30, and the white resin is cured. After the reflective member 90 is arranged, the mask is removed to expose the first terminals 11 from the reflective member 90. The reflective member 90 may further be arranged in a space between the substrate 10 and the lower surfaces of the light-emitting elements 30.

### Step of Placing Substrate 10 on Package Substrate 20

Subsequently, the package substrate 20 is provided, in which the substrate placement region 20r, on which the substrate 10 is to be placed, and the second terminals 22 located outward of the substrate placement region 20r are located at the upper surface 20a side. For example, the package substrate 20 can be provided by forming a conductive member of Cu or the like and the second terminals 22 on a flat plate-shaped support member of metal, ceramic, or the like, by a plating method, a sputtering method, a vapor deposition method, and the like. Subsequently, the substrate 10 on which the light-emitting elements 30 are mounted is placed on the substrate placement region 20r of the package substrate 20. For example, the substrate 10 and the package substrate 20 can be bonded to each other via a bonding member such as a sintered compact including Ag.

### Step of Connecting by Wires 70

Subsequently, each of the first terminals 11 of the substrate 10 is connected to a corresponding one of the second terminals 22 of the package substrate 20 by a corresponding wire 70. For example, each wire 70 is first connected to one of the first terminals 11 of the substrate 10 and then, is connected to a corresponding one of the second terminals 22 of the package substrate 20. By connecting the wire 70 in this order, the top portion of the wire 70 can be positioned closer to the first terminal 11. This can facilitate arranging the wires 70 along a stepped portion between the substrate 10 and the package substrate 20. Thus, in a step of arranging the covering member 80 described below, the amount of a resin located below the wires 70 can be reduced, and the possibility of disconnection of the wires 70 due to thermal expansion of the covering member 80 can be reduced.

### Step of Arranging First Wavelength Conversion Portion 40, Second Wavelength Conversion Portion 50, and Diffusion Portion 60

Subsequently, the first wavelength conversion portion 40 that covers the upper surfaces of the light-emitting elements 30 and from which the first terminals 11 is exposed is arranged on the upper surface 10a of the substrate 10. For example, as the first wavelength conversion portion 40, a member that is processed into a sheet-like shape having a predetermined size is provided in advance, and is disposed on the light-emitting elements 30. The first wavelength conversion portion 40 may be fixed on the light-emitting elements 30 via a light-transmissive bonding member such as a resin, or may be fixed utilizing the tackiness of the first wavelength conversion portion 40 or the like, without using a bonding member. Instead of disposing a member processed into a sheet-like shape on the light-emitting elements 30, the first wavelength conversion portion 40 may be applied onto the light-emitting elements 30 by spraying or the like. Alternatively, the first wavelength conversion portion 40 can be formed by injection molding, transfer molding, compression molding, or the like by using a mold and the like.

Subsequently, the second wavelength conversion portion 50 that covers a part of the first wavelength conversion portion 40 is arranged. For example, the second wavelength conversion portion 50 can be arranged by a method similar to that used for the first wavelength conversion portion 40. Subsequently, the diffusion portion 60 covering the first wavelength conversion portion 40 and the second wavelength conversion portion 50 is arranged. For example, the diffusion portion 60 can be arranged by a method similar to that used for the first wavelength conversion portion 40.

### Step of Arranging Covering Member 80

Subsequently, the covering member 80 covering the first terminals 11, the second terminals 22, and the wires 70 is arranged on the outer peripheral portion of the upper surface 10a of the substrate 10 and the outer peripheral portion of the upper surface 20a of the package substrate 20. For example, the covering member 80 can be arranged by supplying an unhardened resin material at a predetermined position by using a dispenser or the like, and then, hardening the resin. In another example, after the first wavelength conversion portion 40 and the second wavelength conversion portion 50 are arranged, the covering member 80 may be arranged, and then the diffusion portion 60 may be arranged. Through the above-described steps, the light-emitting device 1 is obtained.

### Second Embodiment

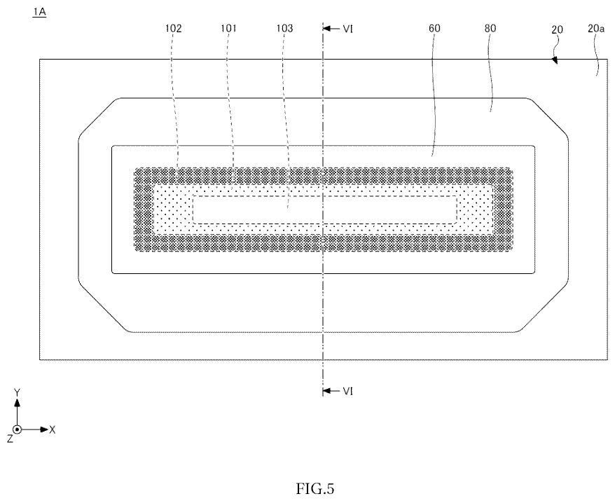

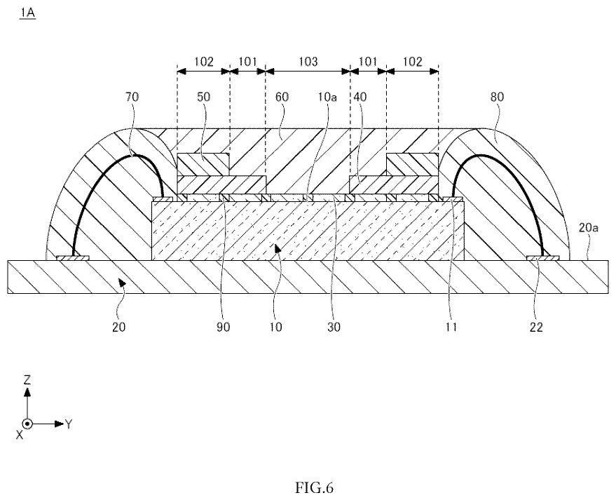

FIG. 5 is a top view schematically illustrating a light-emitting device according to a second embodiment. FIG. 6 is a schematic cross-sectional view taken along line VI-VI in FIG. 5. As illustrated in FIGS. 5 and 6, a light-emitting device 1A according to the second embodiment is different from the light-emitting device 1 according to the first embodiment in that the light-emitting device 1A further includes a third region 103, in addition to the first region 101 and the second region 102. The first region 101, the second region 102, and the third region 103 may be positioned inward of the covering member 80 in a top view. However, the positional relationship among the first region 101, the second region 102, and the third region 103 is not limited to the arrangement illustrated in FIG. 5.

The third region 103 is a region in which the diffusion portion 60 covers the light-emitting elements 30 without interposing the first wavelength conversion portion 40 and the second wavelength conversion portion 50. Light emitted from the light-emitting elements 30 can be extracted from the third region 103 only via the diffusion portion 60. For example, when the light-emitting elements 30 can emit blue light, blue light can be extracted from the third region 103. Blue light has high energy, and thus can be emitted over a farther distance.

In the light-emitting device 1A, the plurality of light-emitting elements 30 can be individually driven. Therefore, for example, when some or all of the plurality of light-emitting elements 30 located in the third region 103 are turned on and all of the plurality of light-emitting elements 30 located in the first region 101 and the second region 102 are turned off, it is possible to extract light only from the third region 103. Furthermore, it is possible to adjust illumination by controlling the number of light-emitting elements 30 caused to emit light, among the plurality of light-emitting elements 30 located in the third region 103. Alternatively, it is possible to adjust illumination by controlling the value of a current flowing in each of the plurality of light-emitting elements 30 located in the third region 103. Similarly to the light-emitting device 1, illumination adjustment and color adjustment can be performed in the first region 101 and the second region 102.

When the light-emitting device 1A is used as the light source of a vehicular headlight, the area size of the first region 101 is preferably larger than the area size of the second region 102 and smaller than the area size of the third region 103 in a top view. The area size of the first region 101 is more preferably in a range from 105% to 130% of the area size of the second region 102 and in a range from 35% to 65% of the area size of the third region 103, in a top view. In rain or fog, light having a higher color temperature scatters more greatly and thus has a lower transmittance. By setting the relationship among the area sizes of the first region 101, the second region 102, and the third region 103 as described above, light having a high color temperature can reach farther, even in rain or fog. As a result, when light is extracted from the first region 101, the second region 102, and the third region 103 in rainy or foggy weather, the brightness of the regions can be made uniform.

### Third Embodiment

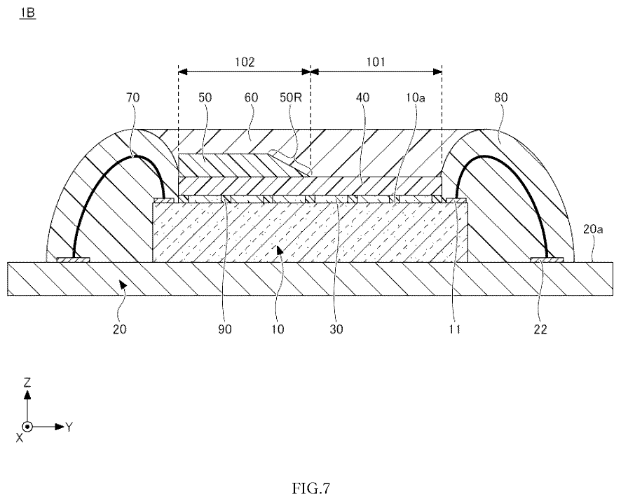

FIG. 7 is a cross-sectional view schematically illustrating a light-emitting device according to a third embodiment. As illustrated in FIG. 7, a light-emitting device 1B according to the third embodiment is different from the light-emitting device 1 according to the first embodiment in that an end portion of the second wavelength conversion portion 50 of the light-emitting device 1B includes a region 50R where its thickness is gradually reduced in a cross-sectional view. An inclined surface of the region 50R may be linear or curved in a cross-sectional view. The shape of the second wavelength conversion portion 50 does not need to be linear or curved, as long as the thickness of the second wavelength conversion portion 50 is gradually reduced. In the second wavelength conversion portion 50, the thicknesses of regions other than the region 50R are substantially constant.

As described above, the light-emitting device 1B includes the region 50R in which the thickness of the second wavelength conversion portion 50 is gradually reduced, and thus, the color is gradually changed in the region 50R, so that the color mixing performance can be improved.

### Fourth Embodiment

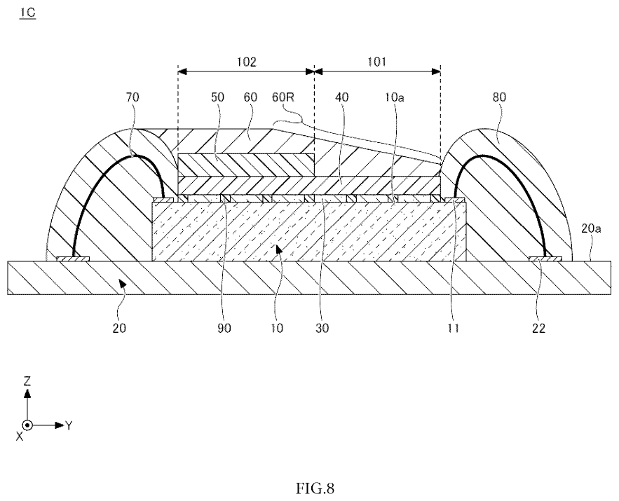

FIG. 8 is a cross-sectional view schematically illustrating a light-emitting device according to a fourth embodiment. As illustrated in FIG. 8, a light-emitting device 1C according to the fourth embodiment is different from the light-emitting device 1 according to the first embodiment in that the light-emitting device 1C includes a region 60R, where the thickness of the diffusion portion 60 is gradually reduced, at an end portion of the diffusion portion 60 in a cross-sectional view. The region 60R includes a boundary between the first region 101 and the second region 102. An inclined surface of the region 60R may be linear or curved in a cross-sectional view. The shape of the diffusion portion 60 does not need to be linear or curved, as long as the thickness of the diffusion portion 60 is gradually reduced. In the diffusion portion 60, the thicknesses of regions other than the region 60R are substantially constant.

As described above, the light-emitting device 1C includes the region 60R, in which the thickness of the diffusion portion 60 is gradually reduced, and thus, the color is gradually changed in the region 60R, so that the color mixing performance can be improved.

The light-emitting device 1C may further include the region 50R in which the thickness of the second wavelength conversion portion 50 is gradually reduced. By providing both the region 50R and the region 60R, the color mixing performing can be further improved.

### Fifth Embodiment

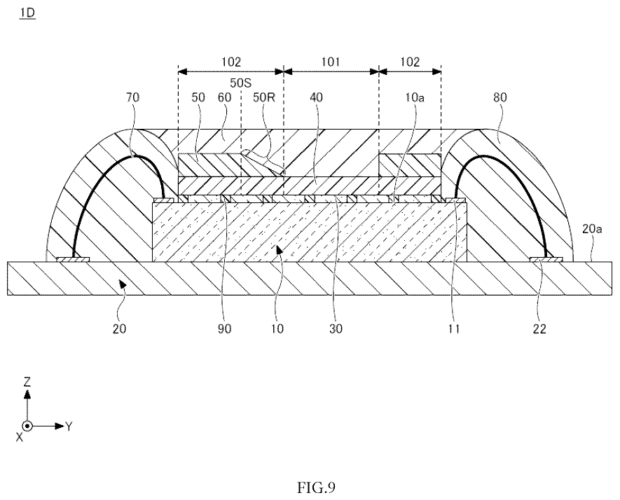

FIG. 9 is a cross-sectional view schematically illustrating a light-emitting device according to a fifth embodiment. As illustrated in FIG. 9, in a light-emitting device 1D according to the fifth embodiment, the boundary between the first wavelength conversion portion 40 and the second wavelength conversion portion 50 is located directly above one or more of the light-emitting elements 30 among the plurality of light-emitting elements 30 in atop view. That is, the boundary (two positions in the example of FIG. 9) between the first region 101 and the second region 102 is positioned directly above one or more of the light-emitting elements 30 among the plurality of light-emitting elements 30. Thus, the color mixing performance can be further improved. Furthermore, a boundary 50S between the region 50R and a region where the thickness of the second wavelength conversion portion 50 is constant is preferably located directly above one or more of the light-emitting elements 30 among the plurality of light-emitting elements 30. Thus, the color mixing performance can be even further improved.

### Sixth Embodiment

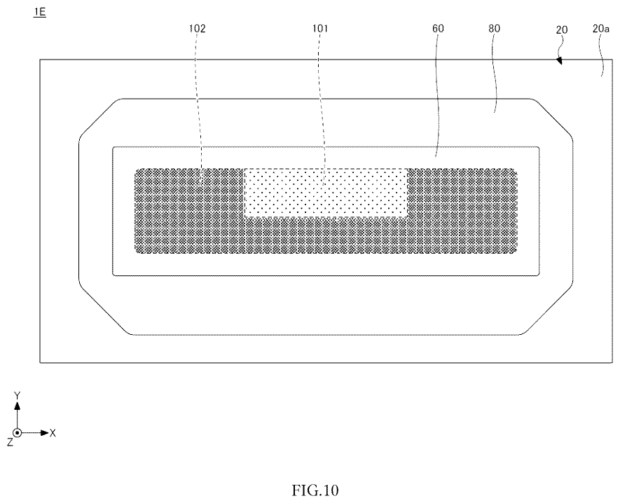

FIG. 10 is a top view schematically illustrating a light-emitting device according to a sixth embodiment. In FIG. 10, for convenience, the first region 101 is indicated by a low-density dot pattern and the second region 102 is indicated by a high-density dot pattern. As illustrated in FIG. 10, in a light-emitting device 1E according to the sixth embodiment, the second region 102 surrounds the first region 101 in a top view.

In the example of FIG. 10, the upper surface 20a of the package substrate 20 has a rectangular shape of which the long sides are parallel to the X direction and the short sides are parallel to the Y direction. Furthermore, the Z direction is a thickness direction of the light-emitting device 1E. In this case, a cross section of the light-emitting device 1E taken along a plane parallel to the YZ plane passing through the first region 101 and the second region 102 is similar to the cross section illustrated in FIG. 4.

The color temperature of light extracted from the first region 101 is higher than the color temperature of light extracted from the second region 102. Therefore, the first region 101 is a region from which light having a higher output than light from the second region 102 can be extracted, and light emitted from the first region 101 can be irradiated to a location farther than light emitted from the second region 102. However, light having a high color temperature is easily scattered by fog or the like, and thus, the vicinity is irradiated with light from the second region 102 surrounding the first region 101 and having a low color temperature. Therefore, it is possible to suitably emit light over a short distance and a long distance. When the light-emitting device 1E is used as a light source of a vehicular headlight, the first region 101 can be utilized as a high-beam region.

Certain embodiments and the like have been described in detail above. However, the disclosure is not limited to the above-described embodiments and the like, and various modifications and substitutions can be made to the above-described embodiments and the like without departing from the scope described in the claims.

What is claimed is:

1. A light-emitting device comprising:
a substrate;
a plurality of light-emitting elements arranged on an upper surface of the substrate, the plurality of light-emitting elements configured to be individually driven;
a first wavelength conversion portion covering at least a portion of at least one of the plurality of light-emitting elements;
a second wavelength conversion portion covering a part of the first wavelength conversion portion; and
a diffusion portion covering the first wavelength conversion portion and the second wavelength conversion portion,
wherein, in a cross-sectional view of the light-emitting device, the light-emitting device comprises:
a first region in which the diffusion portion is arranged above the first wavelength conversion portion without the second wavelength conversion portion between the diffusion portion and the first wavelength conversion portion, and
a second region in which the second wavelength conversion portion and the diffusion portion are sequentially arranged on the first wavelength conversion portion, and
wherein the first region and the second region are configured such that a color temperature of light extracted from the second region is lower than a color temperature of light extracted from the first region.

2. The light-emitting device according to claim 1, wherein
the second wavelength conversion portion comprises a region in which a thickness thereof is gradually reduced in a cross-sectional view at an end portion of the second wavelength conversion portion.

3. The light-emitting device according to claim 1, wherein
the diffusion portion comprises a region in which a thickness thereof is gradually reduced in a cross-sectional view at an end portion of the diffusion portion.

4. The light-emitting device according to claim 1, wherein
a boundary between the first wavelength conversion portion and the second wavelength conversion portion is located directly above one or more light-emitting elements of the plurality of light-emitting elements in a top view of the light-emitting device.

5. The light-emitting device according to claim 1, wherein
the first region is a region from which light having an output higher than an output of light from the second region is extracted, and
the second region surrounds the first region in a top view.

6. The light-emitting device according to claim 1, wherein
an area size of the first region is larger than an area size of the second region in a top view.

7. The light-emitting device according to claim 6, wherein
the area size of the first region is in a range from 105% to 130% of the area size of the second region in a top view.

8. The light-emitting device according to claim 1, further comprising:
a third region in which the diffusion portion covers the plurality of light-emitting elements,
wherein, in the third region, the first wavelength conversion portion and the second wavelength conversion portion are not located between the diffusion portion and the plurality of light-emitting elements.

9. The light-emitting device according to claim 8, wherein
an area size of the first region is larger than an area size of the second region and smaller than an area size of the third region in a top view.

10. The light-emitting device according to claim 9, wherein
the area size of the first region is in a range from 105% to 130% of the area size of the second region and in a range from 35% to 65% of the area size of the third region in a top view.

11. The light-emitting device according to claim 1, wherein
the plurality of light-emitting elements are configured to emit blue light,
the first wavelength conversion portion is configured to be excited by blue light and to emit yellow light, and
the second wavelength conversion portion is configured to be excited by blue light and to emit amber light.
